(19) United States
(12) Patent Application Publication
(10) Pub. No.: US 2020/0152639 A1
(43) Pub. Date: May 14, 2020

(54) SEMICONDUCTOR STRUCTURE AND MANUFACTURING METHOD THEREOF

(71) Applicant: NANYA TECHNOLOGY CORPORATION, New Taipei City (TW)

(72) Inventors: Jui-Wen HO, New Taipei City (TW); Hsu CHIANG, New Taipiei City (TW); Szu-Han CHEN, New Taipei City (TW)

(21) Appl. No.: 16/184,226

(22) Filed: Nov. 8, 2018

(51) Int. Cl. H01L 27/108; H01L 23/532; H01L 21/768; H01L 23/522

(52) U.S. Cl. CPC H01L 27/10885; H01L 27/10888; H01L 27/10829; H01L 21/7682; H01L 23/5226; H01L 23/53295

(57) ABSTRACT

The present disclosure provides a semiconductor structure. The semiconductor structure includes a semiconductor substrate having a base and a plurality of protrusions extending from the base and spaced apart from each other; a first oxide layer substantially disposed between two adjacent protrusions and exposing an upper portion of the protrusion between portions of the first oxide layer; a bit line contact covering the upper portion of the protrusion; a bit line disposed over the bit line contact; a first nitride layer disposed on lateral surfaces of the bit line contact and the bit line and on an upper surface and a sidewall of the first oxide layer exposed to the bit line contact; and a second nitride layer at least formed over the first nitride layer disposed on the lateral surfaces with an interval and connected to the first nitride layer disposed on the sidewall, thereby forming an air gap between the first and second nitride layers.

### TECHNICAL FIELD

The present disclosure relates to a semiconductor structure and semiconductor manufacturing, and more particularly to a trench capacitor of a dynamic random access memory (DRAM) with an air gap for preventing parasitic leakage and a method for forming the trench capacitor.

### DISCUSSION OF THE BACKGROUND

A conventional dynamic random access memory (DRAM) cell 100, as shown in FIG. 1, consists of a transistor T and a capacitor C. The source of the transistor T is connected to a corresponding bit line BL. The drain of the transistor T is connected to a storage electrode of the capacitor C. The gate of the transistor T is connected to a corresponding word line WL. An opposite electrode of the capacitor C is biased with a constant voltage source.

However, as the DRAM cells become increasingly small, the high impact structures of the DRAM cells result in high parasitic capacitance between a bit line and a cell plate of a trench capacitor of the DRAM cell, thereby causing parasitic leakage.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure. The semiconductor structure comprises a semiconductor substrate, a first oxide layer, a bit line contact, a bit line, a first nitride layer, and a second nitride layer. The semiconductor substrate has a base and a plurality of protrusions spaced apart from each other and extending from the base. The first oxide layer is substantially disposed between two adjacent protrusions and exposing an upper portion of the protrusion between portions of the first oxide layer. The bit line contact covers the upper portion. The bit line is disposed over the bit line contact. The first nitride layer is disposed on lateral surfaces of the bit line contact, the bit line, and an upper surface and a sidewall adjacent to the upper surface of the first oxide layer exposed to the bit line contact. The second nitride layer is at least formed over the first nitride layer disposed on the lateral surfaces with an interval and connected to the first nitride layer disposed on the sidewall, thereby forming an air gap between the first nitride layer and the second nitride layer.

In some embodiments, the air gap is a hook-shaped air gap if a height of the upper portion covered by the bit line contact is equal to or greater than 20 nm.

In some embodiments, the air gap is a linear air gap if a height of the upper portion covered by the bit line contact is less than 20 nm.

In some embodiments, the second nitride layer is further connected to the upper surface.

In some embodiments, the semiconductor structure further comprises a coverage layer disposed over the second nitride layer.

In some embodiments, the first nitride layer is further formed over the coverage layer.

In some embodiments, the semiconductor structure further comprises a hard mask pattern formed over the bit line, and a lateral surface of the hard mask pattern is covered by the first nitride layer.

In some embodiments, the first nitride layer is further formed over the hard mask pattern.

In some embodiments, the bit line contact layer is further disposed on a portion of the upper surface.

Another aspect of the present disclosure provides a method of manufacturing a semiconductor structure. The method comprises providing a semiconductor substrate; forming a plurality of trenches spaced apart from each other on the semiconductor substrate; disposing a first dielectric layer within the trenches; forming a bit line contact hole on portions of the first dielectric layer and the semiconductor substrate; disposing a contact layer within the bit line contact hole; disposing a bit line conductive layer over the contact layer; removing portions of the contact layer and the bit line conductive layer to expose portions of an upper surface and a sidewall of the first oxide layer and to form a bit line contact and a bit line; forming a first nitride layer over lateral surfaces of the bit line contact and the bit line and the upper surface and the sidewall of the first oxide layer; forming a second oxide layer over the first nitride layer; forming a second nitride layer over the second oxide layer; and removing the second oxide layer to form an air gap between the first nitride layer and the second nitride layer.

In some embodiments, the air gap is a linear air gap if a depth of the bit line contact hole is less than 20 nm.

In some embodiments, the air gap is a hook-shaped air gap if the depth of the bit line contact hole is equal to or greater than 20 nm.

In some embodiments, the first nitride layer is further formed on an upper surface of the first oxide layer and a top surface of the semiconductor substrate.

In some embodiments, the first nitride layer disposed on the upper surface and the top surface is removed after the forming of the second oxide layer.

In some embodiments, portions of the first oxide layer are removed to expose an inner surface of the first oxide layer and a sidewall of the semiconductor substrate.

In some embodiments, the second nitride layer is further disposed on the inner surface of the first oxide layer and the top surface and the sidewall of the semiconductor substrate.

In some embodiments, the method further comprises a step of forming a coverage layer to cover the sidewall and a portion of the top surface of the semiconductor substrate, the inner surface of the first oxide layer, and the second nitride layer.

In some embodiments, the method further comprises a step of disposing an insulator layer over the semiconductor substrate before forming the trenches, wherein the insulator layer is removed after filling the first dielectric layer within the recesses.

In some embodiments, the first insulator layer is comprised of an overlying layer of silicon nitride and an underlying layer of silicon dioxide, and the first insulator layer is disposed on the top surface of the semiconductor substrate.

In some embodiments, the method further comprises a step of disposing an inter-layer insulator layer over the semiconductor substrate and the first dielectric layer before forming the bit line contact hole.

In some embodiments, the method further comprises a step of performing a chemical mechanical polishing procedure to remove portions of the first oxide layer from a top surface of the first insulator layer.

With the above-mentioned configurations, the parasitic capacitance between the bit line and the cell plate is reduced to prevent parasitic leakage and thus improve the electrical performance of the DRAM.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 shows a circuit diagram of a DRAM cell according to the prior art.

FIG. 2A is a cross-sectional view of a semiconductor structure in accordance with the present disclosure.

FIG. 2B is a cross-sectional view of a semiconductor structure in accordance with the present disclosure.

FIGS. 3A to 3O are schematic views of manufacturing a semiconductor structure by a method in accordance with some embodiments of the present disclosure.

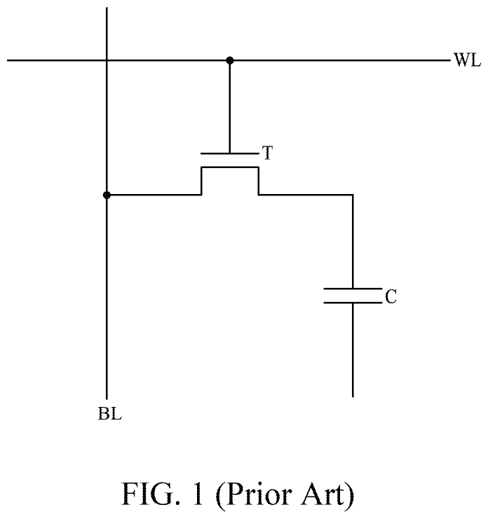

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

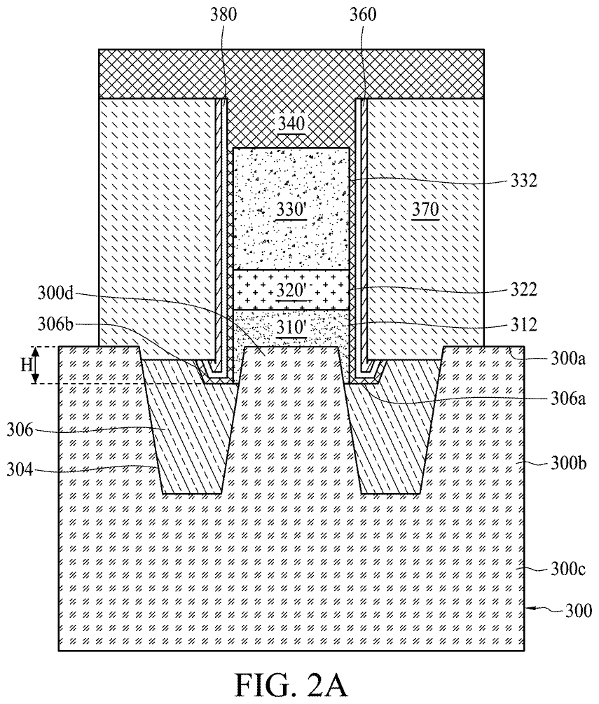

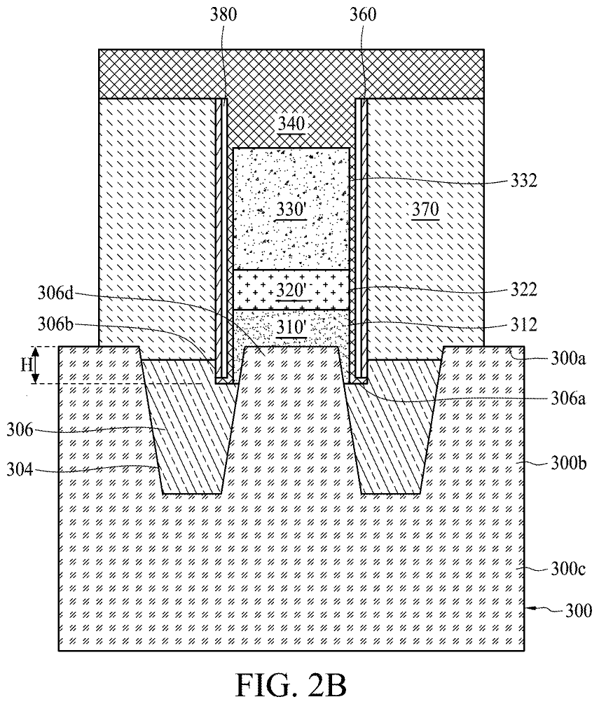

FIG. 2A is a cross-sectional view of a semiconductor structure in accordance with the present disclosure. The semiconductor structure includes a semiconductor substrate 300, a first oxide layer 306, a bit line contact 310′, a bit line 320′, a first nitride layer 340, and a second nitride layer 360. The semiconductor substrate 300 has a base 300c and a plurality of protrusions 300b spaced apart from each other and extending from the base 300c. The first oxide layer 306 is substantially disposed between two adjacent protrusions 300b and exposes an upper portion 300d of the protrusion 300b between portions of the first oxide layer 306. A bit line contact 310′ covers the upper portion 300d, and a bit line 320′ is disposed over the bit line contact 310′. The first nitride layer 340 is disposed on lateral surfaces 312 and 322 of the bit line contact 310′ and the bit line 320′, respectively, and on an upper surface 306a and a sidewall 306b adjacent to the upper surface 306a of the first oxide layer 306 exposed to the bit line contact 310′. The second nitride layer 360 is at least formed over the first nitride layer 340 disposed on the lateral surfaces 312, 322 with an interval and is connected to the first nitride layer 340 disposed on the sidewall 306b, thereby forming an air gap 380 between the first nitride layer 340 and the second nitride layer 360.

In some embodiments, the semiconductor substrate 300 is a semiconductor wafer. In some embodiments, the upper surface 306a of the first oxide layer 306 and a top surface 300a of the semiconductor substrate 300 are at different horizontal levels. In some embodiments, the composition of the first nitride layer 340 is the same as that of the second nitride layer 360. In some embodiments, the first nitride layer 340 and the second nitride layer 360 include silicon nitride.

In some embodiments, the semiconductor structure further comprises a hard mask pattern 330′ formed over the bit line 320′, and a lateral surface 332 of the hard mask pattern 330′ is covered by the first nitride layer 340. In some embodiments, the first nitride layer 340 is formed over of the hard mask pattern 330′. In some embodiments, the semiconductor structure further comprises a coverage layer 370 disposed on the lateral side of the second nitride layer 360. In some embodiments, the first nitride layer 340 is further formed over the coverage layer 370. In some embodiments, the air gap 380 is a hook-shaped air gap if a height H of the upper portion 300d covered by the bit line contact 310′ is equal to or greater than 20 nm.

In some embodiments, the air gap 380 is a linear air gap if a height of the upper portion 300d covered by the bit line contact 310′ is less than 20 nm as shown in FIG. 2B. In some embodiments, the first nitride layer 340 is further disposed on a portion of the upper surface 306a of the first oxide layer 306.

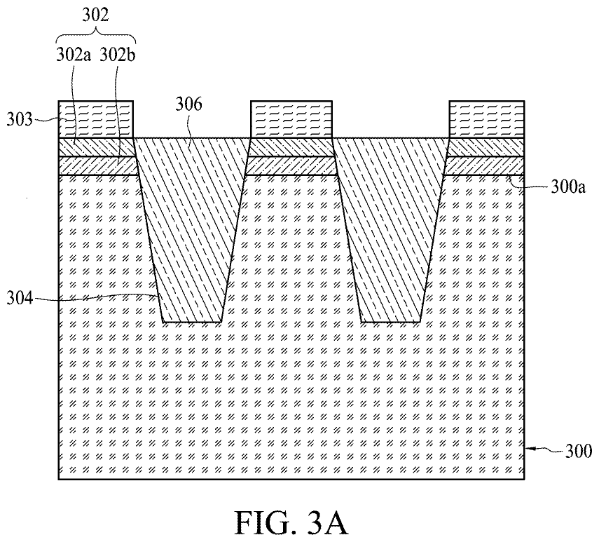

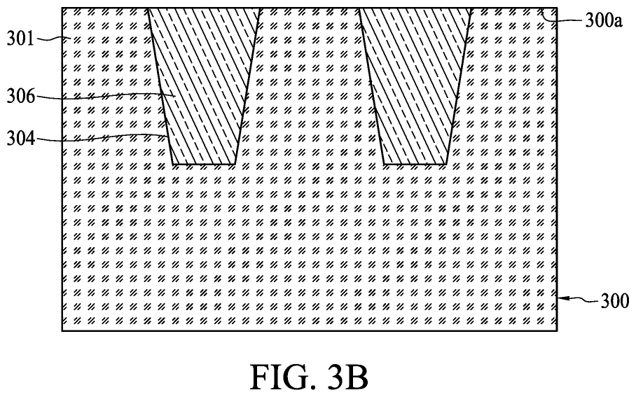

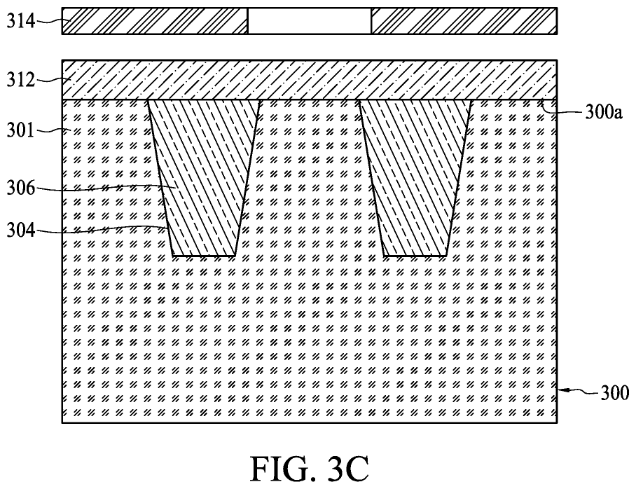

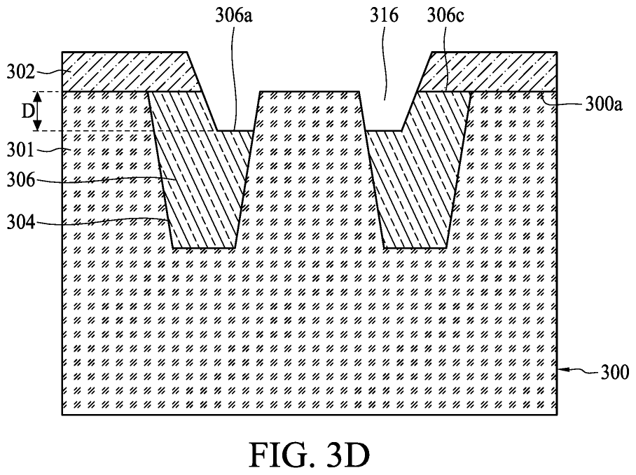

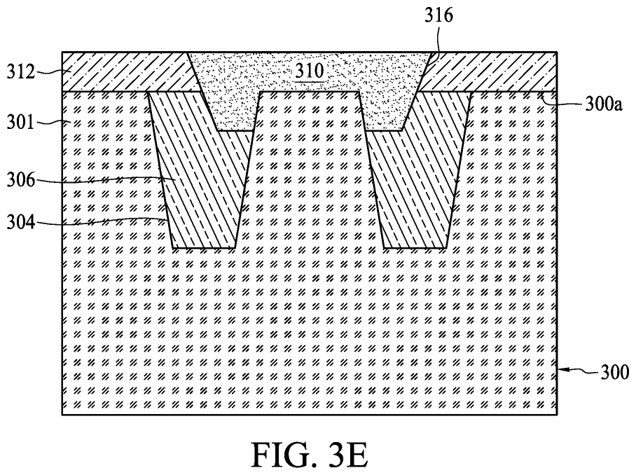

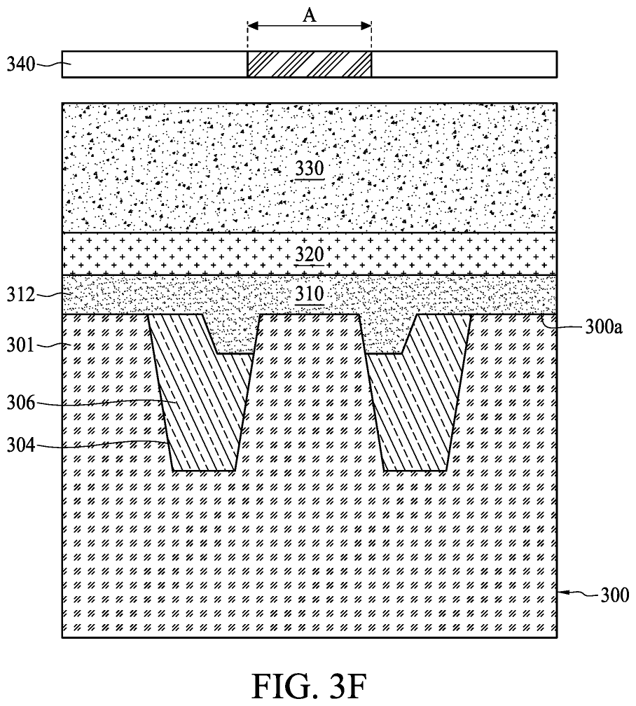

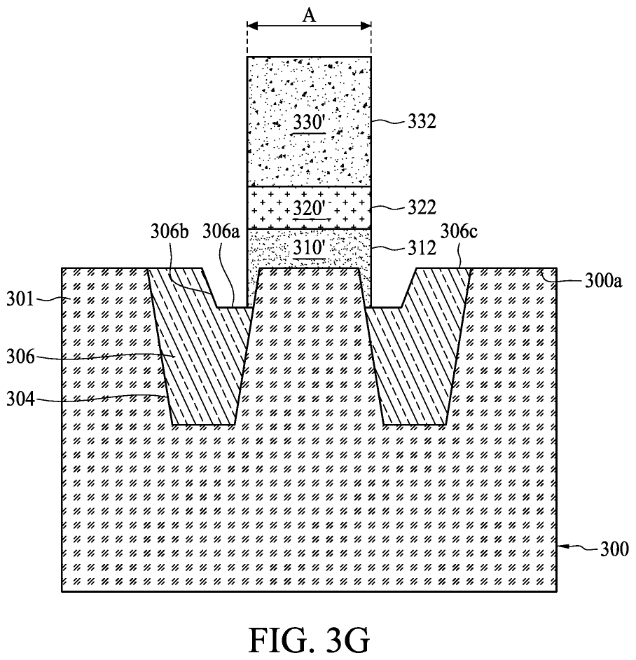

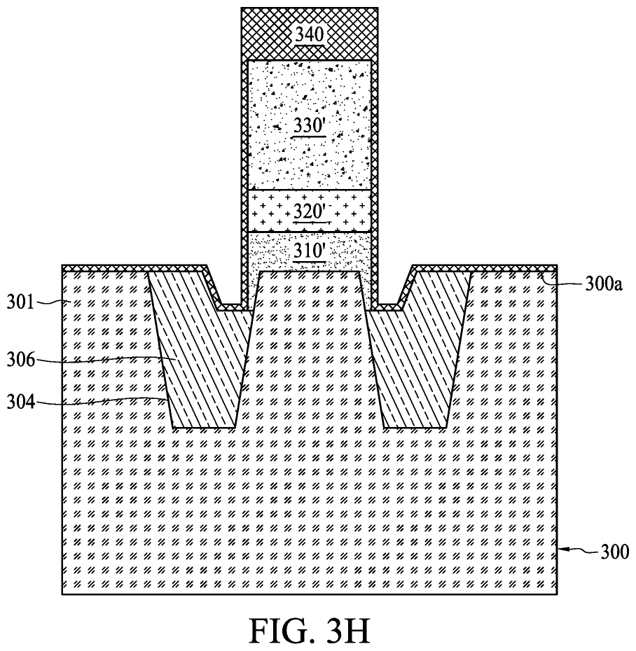

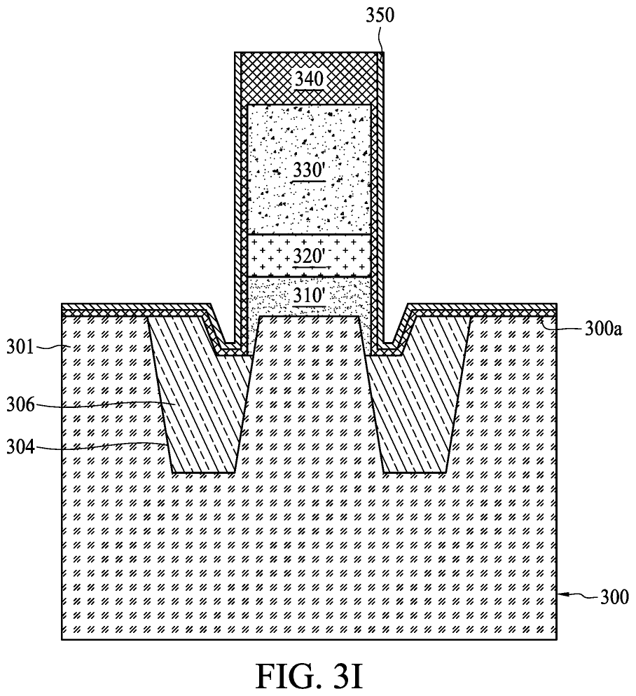

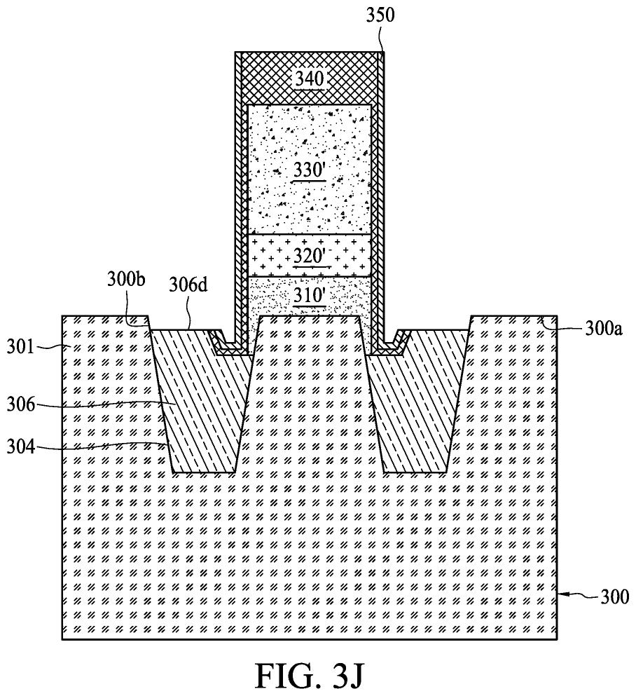

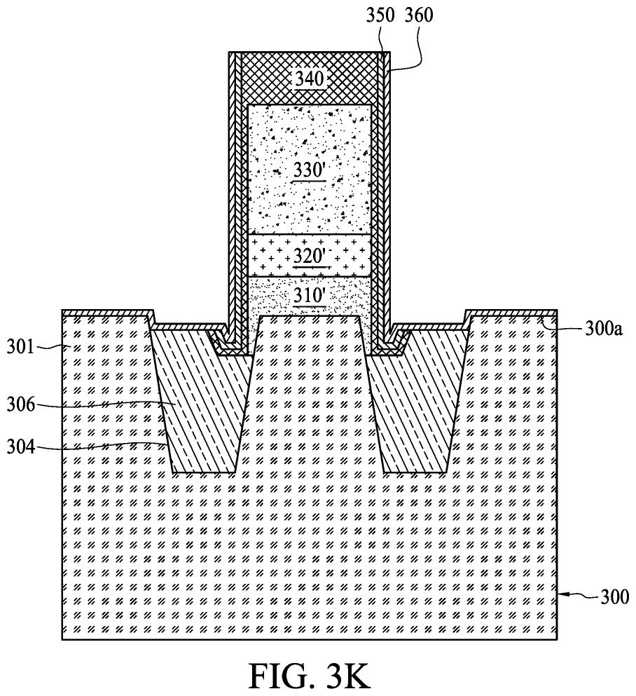

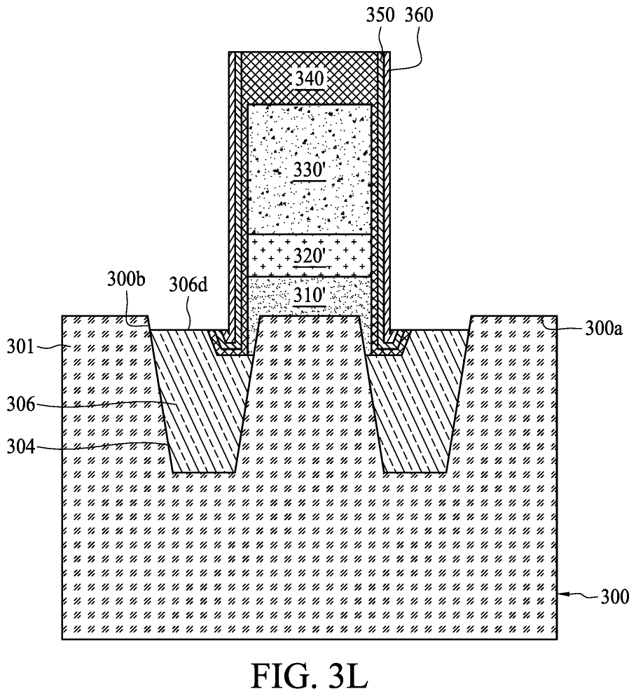

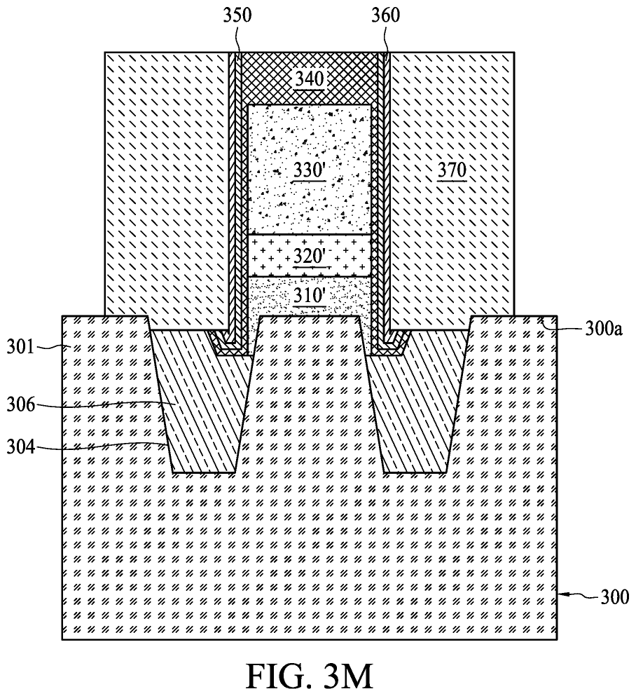

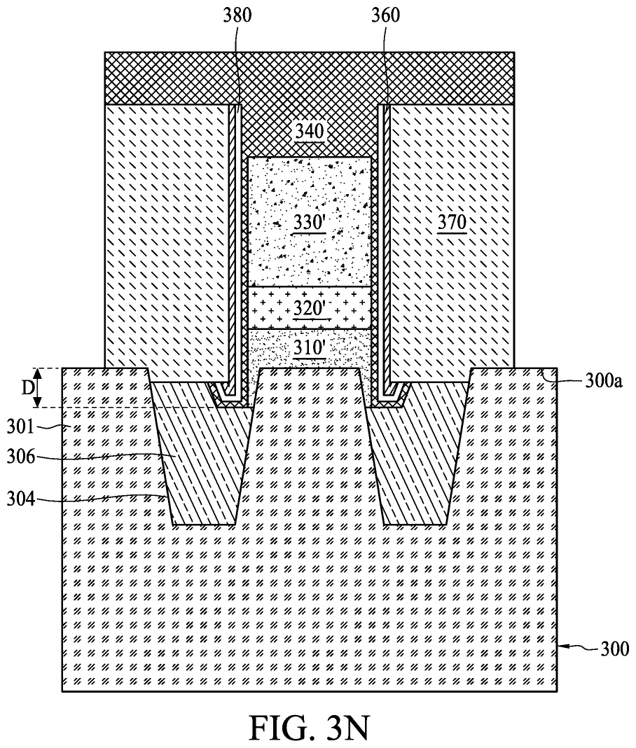

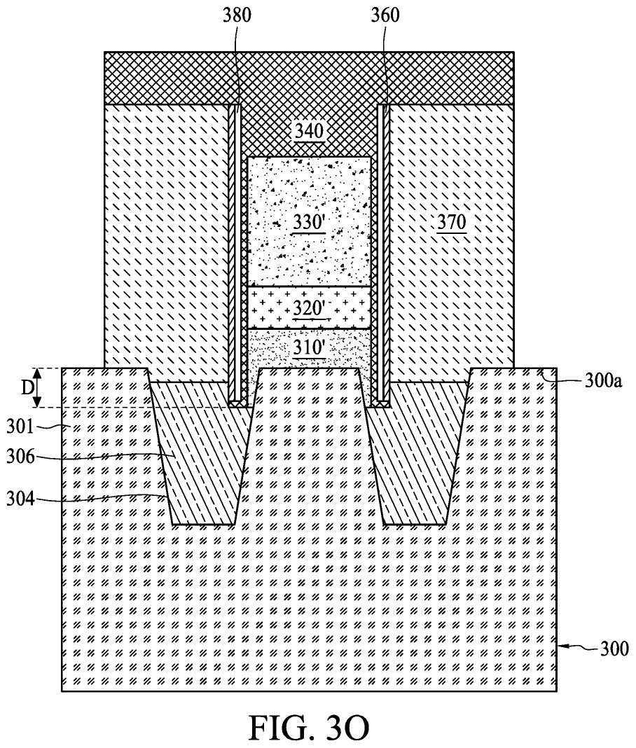

Referring to FIG. 3A, a semiconductor substrate 300 with a first insulator layer 302, a plurality of trenches 304, and a first oxide layer 306 is provided. The first insulator layer 302 is formed over a top surface 300a of the semiconductor substrate 300, and the deep narrow trenches 304 are etched into the semiconductor substrate 300.

In some embodiments, after the forming of the first insulator layer 302 over the top surface 300a of the semiconductor substrate 300, a masking step is performed using a patterned photoresist 303 that is open to the trenches 304, and an etching is then performed to recess the first oxide layer 306 in the trenches 304. In some embodiments, the patterned photoresist 303 is disposed over the first insulator layer 302, such that the predetermined portion of the first insulator layer 302 and the semiconductor substrate 300 are exposed through the patterned photoresist 303, and then the predetermined portion of the first insulator layer 302 and the semiconductor substrate 300 is removed by any suitable operation such as reactive ion etching (RIE) or other suitable operation to define the trenches 304. In some embodiments, the semiconductor substrate 300 is a semiconductor wafer. In some embodiments, the first insulator layer 302 is a composite insulator layer, comprised of an overlying layer of silicon nitride 302a and an underlying layer of silicon dioxide 302b, and is disposed on the top surface of the semiconductor substrate 300.

Referring to FIG. 3B, the first oxide layer 306 is deposited to completely fill the trenches 304. In some embodiments, a shallow trench isolation (STI) process is performed so that the first oxide layer 306 defining an active region 301 is disposed on the semiconductor substrate 300. In some embodiments, the first oxide layer 306 is disposed to a thickness sufficient to fill the trenches 304. In some embodiments, a chemical mechanical polishing (CMP) procedure is used to remove portions of the first oxide layer 306 from a top surface of the first insulator layer 302, resulting in a planarized, active region 301. In some embodiments, the first oxide layer 306 filling the trench 304 is in a funnel configuration. In some embodiments, the first oxide layer 306 includes silicon oxide. In some embodiments, the trenches 304 are substantially filled with the first oxide layer 306 after the removal and cleaning of the patterned photoresist 303. In some embodiments, the first insulator layer 302 is removed before the trenches 304 are filled with the first oxide layer 306.

Referring to FIG. 3C, a second insulator layer 312 is formed over the first oxide layer 306 and the active region 301.

In FIG. 3C, a bit line contact mask 314 is further formed over the second insulator layer 312. In some embodiments, the bit line contact mask 314 is a line mask and the formation thereof includes selectively etching the second insulator layer 312 and the first oxide layer 306. In some embodiments, the etching process stops at the semiconductor substrate 300. In some embodiments, the second insulator layer 312 and the first oxide layer 306 are sequentially etched using the bit line contact mask 314 as an etch mask; thus, the bit line contact hole 316 is formed, as shown in FIG. 3D. In some embodiments, the bit line contact hole 316 has a depth distance D from a front surface 306c to an upper surface 306a.

Referring to FIG. 3E, a contact layer 310 is formed over the active region 301. In some embodiments, the contact layer 310 is deposited to completely fill the bit line contact hole 316. In some embodiments, the contact layer 310 is in contact with the second insulator layer 312, the semiconductor substrate 300, and the first oxide layer 306.

Reference to FIG. 3F, a bit line conductive layer 320 is disposed over the contact layer 310, and a hard mask layer 330 is disposed over the bit line conductive layer 320. In some embodiments, the bit line conductive layer 320 includes tungsten.

After the forming of the hard mask layer 330 over the bit line conductive layer 320, the hard mask layer 330, the bit line conductive layer 320, and the bit line contact layer 320 are etched using a bit line mask 340 defining a bit line region A, such that the hard mask pattern 330′, the bit line 320′, and the bit line contact 310′ are formed, as shown in FIG. 3G. In some embodiments, a sidewall 306b of the first oxide layer 306 and a portion of an upper surface 306a of the first oxide layer 306 are exposed to the contact layer 310. In some embodiments, the sidewall 306b is adjacent to the upper surface 306a. In some embodiments, the sidewall 306b is a tapered and sloped sidewall tapering from a front surface 306c to the first oxide layer 306. In some embodiments, the upper surface 306a is substantially parallel to the front surface 306c. In some embodiments, the bit line contact 310′ has a first lateral surface 312 substantially perpendicular to the upper surface of the first oxide layer 306. In some embodiments, the bit line 320′ has a second lateral surface 322, which has a slope that is continuous with the first lateral surface of the bit line contact 310′. In some embodiments, the hard mask pattern 330′ has a third lateral surface 332, which has a slope that is continuous with the second lateral surface 322 of the bit line 320′.

Referring to FIGS. 3G and 3H, a first nitride layer 340 is at least disposed on lateral surfaces 312, 322, 332 of the bit line contact 310′, the bit line 320′, and the hard mask pattern 330′, respectively, and on the upper surface 306a and the sidewall 306b of the first oxide layer 306. In some embodiments, the first nitride layer 340 is further disposed on the front surface 306c of the first oxide layer 306 and the top surface 300a of the semiconductor substrate 300. In some embodiments, the first nitride layer includes silicon nitride.

Referring to FIG. 31, a second oxide layer 350 is formed over the first nitride layer 340. In some embodiments, the second oxide layer 350 is formed over the lateral surfaces 312, 322, 332 of the bit line contact 310′, the bit line 320′, and the hard mask pattern 330′, respectively, and on the upper surface 306a and the sidewall 306b of the first oxide layer 306. In some embodiments, the second oxide layer 350 is further formed over the front surface 306c of the first oxide layer 306 and the top surface 300a of the semiconductor substrate 300.

Referring to FIG. 3J, portions of the first nitride layer 340 and the second oxide layer 350 are removed. In some embodiments, the first nitride layer 340 and the second oxide layer 350 are formed over the front surface 306c of the first oxide layer 306 and the top surface 300a of the semiconductor substrate 300. In some embodiments, an upper portion of the first oxide layer 306 is further removed. In some embodiments, the upper surface 306a of the first oxide layer 306 and the top surface 300a of the semiconductor substrate 300 are at the same horizontal level before the upper portion of the first oxide layer 306 is removed. In some embodiments, an inner surface 306d of the first oxide layer 306 and a portion of sidewall 300b of the semiconductor substrate 300 are exposed after the upper portion of the first oxide layer 306 is removed. In some embodiments, the inner surface 306d of the first oxide layer 306 and the top surface 300a of the semiconductor substrate 300 are at different horizontal levels.

Referring to FIG. 3K, a second nitride layer 360 is at least formed on the second oxide layer 350. In some embodiments, the second nitride layer 360 is further disposed on the inner surface 306d of the first oxide layer 306, the top surface 300a of the semiconductor substrate 300, and the sidewall 300b of the semiconductor substrate 300.

Referring to FIG. 3L, portions of the second nitride layer 360 disposed on the inner surface 306d of the first oxide layer 306 and on the top surface 300a and the sidewall 300b of the semiconductor substrate 300 are removed to expose the inner surface 306d, the top surface 300a, and the sidewall 300b.

Referring to FIG. 3M, a coverage layer 370 is formed to cover the sidewall 300b and a portion of the top surface 300a of the semiconductor substrate 300, the inner surface 306d of the first oxide layer 306, and the second nitride layer 360.

Referring to FIG. 3N, the second oxide layer 350 is removed to form an air gap 380. In some embodiments, the air gap 380 is a hook-shaped air gap if a depth D of the bit line contact hole 316 shown in FIG. 3D is substantially equal to or greater than 20 nm. In some embodiments, the air gap 380 is a linear air gap, as shown in FIG. 3O, if a depth D of the bit line contact hole 316 shown in FIG. 3D is less than 20 nm.

In conclusion, with the above-mentioned configurations, the parasitic capacitance between the bit line and the cell plate is reduced to prevent parasitic leakage and thus improve the electrical performance of the DRAM.

One aspect of the present disclosure provides a semiconductor substrate. The semiconductor structure comprises a semiconductor substrate, a first oxide layer, a bit line contact, a bit line, a first nitride layer, and a second nitride layer. The semiconductor substrate has a base and a plurality of protrusions extending from the base and spaced apart from each other. The first oxide layer is substantially disposed between two adjacent protrusions and exposes an upper portion of the protrusion between portions of the first oxide layer. The bit line contact covers the upper portion. The bit line is disposed over the bit line contact. The first nitride layer is disposed on lateral surfaces of the bit line contact, the bit line, and an upper surface and a sidewall adjacent to the upper surface of the first oxide layer exposed to the bit line contact. The second nitride layer is at least formed over the first nitride layer disposed on the lateral surfaces with an interval and is connected to the first nitride layer disposed on the sidewall, thereby forming an air gap between the first nitride layer and the second nitride layer.

Another aspect of the present disclosure provides a method of manufacturing a semiconductor structure. The method comprises providing a semiconductor substrate; forming a plurality of trenches spaced apart from each other on the semiconductor substrate; disposing a first dielectric layer within the trenches; forming a bit line contact hole on portions of the first dielectric layer and the semiconductor substrate; disposing a contact layer within the bit line contact hole; disposing a bit line conductive layer over the contact layer; removing portions of the contact layer and the bit line conductive layer to expose portions of an upper surface and a sidewall of the first oxide layer and form a bit line contact and a bit line; forming a first nitride layer over lateral surfaces of the bit line contact and the bit line and over the upper surface and the sidewall of the first oxide layer; forming a second oxide layer over the first nitride layer; forming a second nitride layer over the second oxide layer; and removing the second oxide layer to form an air gap between the first nitride layer and the second nitride layer.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor structure, comprising:
a semiconductor substrate having a base and a plurality of protrusions extending from the base and spaced apart from each other;
a first oxide layer substantially disposed between two adjacent protrusions of the plurality of protrusions and exposing an upper portion of one of the plurality of protrusions between portions of the first oxide layer;
a bit line contact covering the upper portion of the protrusion;
a bit line disposed over the bit line contact;
a first nitride layer disposed on lateral surfaces of the bit line contact and the bit line and on an upper surface and a sidewall adjacent to the upper surface of the first oxide layer exposed to the bit line contact, wherein the upper surface of the first oxide layer is lower than a top surface of the upper portion of the one of the plurality of protrusions;
a second nitride layer at least separately formed over the first nitride layer disposed on the lateral surfaces, thereby forming an air gap between the first nitride layer and the second nitride layer.

2. The semiconductor structure of claim 1, wherein the air gap is a hook-shaped air gap if a height of the upper portion covered by the bit line contact is equal to or greater than 20 nm, and the air gap is a linear air gap if the height of the upper portion covered by the bit line contact is less than 20 nm.

3. (canceled)

4. The semiconductor structure of claim 2, wherein the second nitride layer is further connected to the upper surface of the first oxide layer.

5. The semiconductor structure of claim 1, further comprising a coverage layer disposed over the second nitride layer.

6. The semiconductor structure of claim 1, wherein the first nitride layer is further formed over the coverage layer.

7. The semiconductor structure of claim 1, further comprising a hard mask pattern formed over the bit line, wherein a lateral surface of the hard mask pattern is covered by the first nitride layer.

8. The semiconductor structure of claim 7, wherein the first nitride layer is further formed over the hard mask pattern.

9. The semiconductor structure of claim 1, wherein the bit line contact is further disposed on a portion of the upper surface of the first oxide layer.

10. A method of manufacturing a semiconductor structure, comprising:
providing a semiconductor substrate;
forming a plurality of trenches spaced apart from each other on the semiconductor substrate;
disposing a first dielectric layer within the trenches;
forming a bit line contact hole on portions of the first dielectric layer and the semiconductor substrate;
disposing a contact layer within the bit line contact hole;
disposing a bit line conductive layer over the contact layer;
removing portions of the contact layer and the bit line conductive layer to expose portions of an upper surface and a sidewall of the first oxide layer and to form a bit line contact and a bit line;
forming a first nitride layer over lateral surfaces of the bit line contact and the bit line and over the upper surface and the sidewall of the first oxide layer;
forming a second oxide layer over the first nitride layer;
forming a second nitride layer over the second oxide layer; and
removing the second oxide layer to form an air gap between the first nitride layer and the second nitride layer.

11. The method of claim 10, wherein the air gap is a linear air gap if a depth of the bit line contact hole is less than 20 nm.

12. The method of claim 10, wherein the air gap is a hook-shaped air gap if a depth of the bit line contact hole is equal to or greater than 20 nm.

13. The method of claim 10, wherein the first nitride layer is further formed on an upper surface of the first oxide layer and a top surface of the semiconductor substrate.

14. The method of claim 13, wherein after the forming of the second oxide layer, the first nitride layer formed on the upper surface of the first oxide layer and the top surface of the semiconductor substrate is removed.

15. The method of claim 14, wherein portions of the first oxide layer are removed to expose an inner surface of the first oxide layer and a sidewall of the semiconductor substrate.

16. The method of claim 15, wherein the second nitride layer is further formed on the inner surface of the first oxide layer and the top surface and the sidewall of the semiconductor substrate.

17. The method of claim 15, further comprising:
forming a coverage layer to cover the sidewall and a portion of the top surface of the semiconductor substrate 300, the inner surface of the first oxide layer, and the second nitride layer.

18. The method of claim 10, further comprising:
disposing an insulator layer over the semiconductor substrate before forming the trenches, wherein the insulator layer is removed after filling the first dielectric layer within the recesses.

19. The method of claim 10, wherein the first insulator layer comprised of an overlying layer of silicon nitride and an underlying layer of silicon dioxide is formed on the top surface of the semiconductor substrate.

20. The method of claim 10, further comprising:
disposing an inter-layer insulator layer over the semiconductor substrate and the first dielectric layer before forming the bit line contact hole.

21. The method of claim 10, further comprising:
performing a chemical mechanical polishing procedure to remove portions of the first oxide layer from a top surface of the first insulator layer.
